(19) United States
(12) Patent Application Publication
(10) Pub. No.: US 2007/0173057 A1
(43) Pub. Date: Jul. 26, 2007

(54) METHOD FOR FABRICATING STORAGE NODE CONTACT IN SEMICONDUCTOR DEVICE

(75) Inventors: Min-Suk Lee, Icheon-shi (KR); Jae-Young Lee, Icheon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Icheon-si (KR)

(21) Appl. No.: 11/567,213

(22) Filed: Dec. 6, 2006

(30) Foreign Application Priority Data
Jan. 6, 2006 (KR) 10-2006-0001835

(51) Int. Cl. H01L 21/4763

(52) U.S. Cl. 438/640; 257/E21.578

(57) ABSTRACT

A method for fabricating a storage node contact in a semiconductor device includes forming a plurality of bit line patterns, each bit line pattern including a bit line hard mask formed over a bit line conductive layer, forming an inter-layer insulation layer filled between the bit line patterns, planarizing the inter-layer insulation layer until top portions of the bit line hard masks are exposed, partially etching the inter-layer insulation layer to form first open regions, enlarging a width of the first open regions, forming a capping layer to cover the top portions of the bit line hard masks and to cover a surface of the first open regions, etching the capping layer and remaining portions of the inter-layer insulation layer between the bit line patterns to form second open regions below the first open regions, and forming storage node contacts filling in the first and second open regions.

### BACKGROUND OF THE INVENTION

The present invention relates to a method for fabricating a semiconductor device, and more particularly, to a method for fabricating a storage node contact using a line type self-aligned contact etching process.

When an 80 nm level technology using a line type self-aligned contact (SAC) etching process is applied, storage node contacts and storage nodes may be patterned using a KrF photoresist layer and a storage node contact (SNC) key open (KO) etching process may be abridged. Thus, costs can be reduced.

However, a storage node contact formation process using the conventional line type SAC etching process has limitations as described in the following drawings.

FIG. 1A illustrates a micrographic view of a profile of bit line patterns after an etching process is performed to form conventional storage node contacts. FIG. 1B illustrates a micrographic view of bit line patterns damaged after an etching process is performed to form storage node contact spacers. FIG. 1C illustrates a micrographic view of bit line patterns after a storage node contact plug polysilicon (SPP) chemical mechanical polishing (CMP) process is performed.

Referring to FIG. 1A, a poorly formed bit line profile in spire form is generated. That is, a lessening process has been used in a conventional bit line formation process in accordance with demands of conventional devices. The lessening process continuously reduces a final inspection critical dimension (FICD) to become smaller than a mask critical dimension (CD).

The lessening process artificially reduces critical dimensions using etch chemistry. In a device under 80 nm level, a profile of nitride-based bit line hard mask layers becomes vulnerable, resulting in a spire type profile having a larger bottom width than an upper width. The spire type profile further deteriorates while performing a high density plasma (HDP) gap-fill process for forming a subsequent inter-layer insulation layer. The spire type profile becomes even sharper, and in a worse case, bends during an etching process, i.e, sputtering process, performed during a high density plasma (HDP) deposition process.

Referring to FIG. 1B, asymmetrical sidewalls and a prominence type profile are generated. When the line type SAC etching process is performed by a basic process flow, the asymmetrical sidewalls result, affected by the above described profile of the bit line patterns which are bending and sharpening. Also, the bit line patterns obtain the prominence type profile because resistance to the SAC etch recipe decreases due to the poorly formed bit line profile. The sidewalls refer to remaining portions of the inter-layer insulation layer on sidewalls of the bit line patterns after an etching process is performed to form the storage node contacts. The word asymmetrical is used because a portion of the remaining inter-layer insulation layer on the left side of the bit line pattern and another portion of the remaining inter-layer insulation layer on the right side of the bit line pattern differ in thickness. Sidewalls of the bit line patterns become vulnerable due to the asymmetrical sidewalls, and thus, the sidewalls of the bit line patterns become vulnerable to an SAC fail. It is difficult for the prominence type profile to maintain a sufficient amount of margin, i.e., remaining portions of the nitride-based layers and CD, during an isolation process of a subsequent storage node contact plug polysilicon (SPP) CMP process. It is important to maintain an adequate thickness of the sidewalls to prevent the SAC fail and reduce a capacitance (Cb) value of the bit line patterns. However, experiments show that the thickness of the sidewalls does not increase substantially even when a thickness of the nitride-based layers increases. Due to the sloped profile, a large amount of the nitride-based layers is etched away, and thus, a desired thickness of the sidewalls is not maintained.

Referring to FIG. 1C, a process margin decreases due to the prominence type profile during an SPP CMP process.

The above mentioned limitations are typically generated by the spire type profile of the bit line patterns.

### SUMMARY OF THE INVENTION

The present invention provides a method for fabricating a storage node contact in a semiconductor, which can prevent a self-aligned contact (SAC) failure generated by a spire type profile of bit line patterns.

In accordance with an embodiment of the present invention, there is provided a method for fabricating a storage node contact in a semiconductor device, including: forming a plurality of bit line patterns, each bit line pattern including a bit line hard mask formed over a bit line conductive layer; forming an inter-layer insulation layer filled between the bit line patterns; planarizing the inter-layer insulation layer until top portions of the bit line hard masks are exposed; partially etching the inter-layer insulation layer to form first open regions; enlarging a width of the first open regions; forming a capping layer to cover the top portions of the bit line hard masks and to cover a surface of the first open regions; etching the capping layer and remaining portions of the inter-layer insulation layer between the bit line patterns to form second open regions below the first open regions; and forming storage node contacts filling in the first and second open regions.

### BRIEF DESCRIPTION OF THE DRAWINGS

The above features of the present invention will become better understood with respect to the following description of the exemplary embodiments given in conjunction with the accompanying drawings, in which:

FIG. 1A illustrates a micrographic view of a profile of bit line patterns after an etching process is performed to form conventional storage node contacts;

FIG. 1B illustrates a micrographic view of conventional bit line patterns damaged after an etching process is performed to form storage node contact spacers;

FIG. 1C illustrates a micrographic view of conventional bit line patterns after a storage node contact plug polysilicon (SPP) chemical mechanical polishing (CMP) process is performed;

FIGS. 2A to 2F illustrate cross-sectional views to describe a method for fabricating a storage node contact in accordance with an embodiment of the present invention;

FIG. 3A illustrates a micrographic view of a profile of bit line patterns after an etching process for forming storage node contacts is performed and a capping layer is formed in accordance with an embodiment of the present invention;

FIG. 3B illustrates a micrographic view of a profile of bit line patterns after an etching process is performed to form storage node contact spacers in accordance with an embodiment of the present invention; and

FIG. 3C illustrates a micrographic view of a profile of bit line patterns after a SPP CMP process is performed in accordance with an embodiment of the present invention.

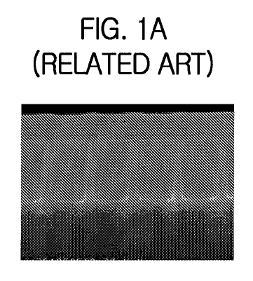

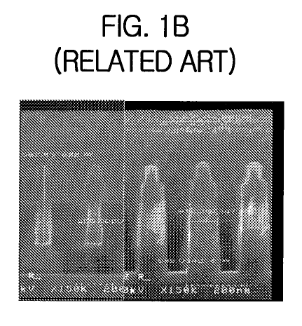

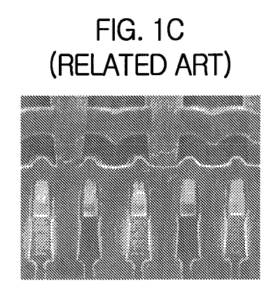

### DETAILED DESCRIPTION OF THE INVENTION

A method for fabricating a storage node contact in a semiconductor device in accordance with exemplary embodiments of the present invention will be described in detail with reference to the accompanying drawings.

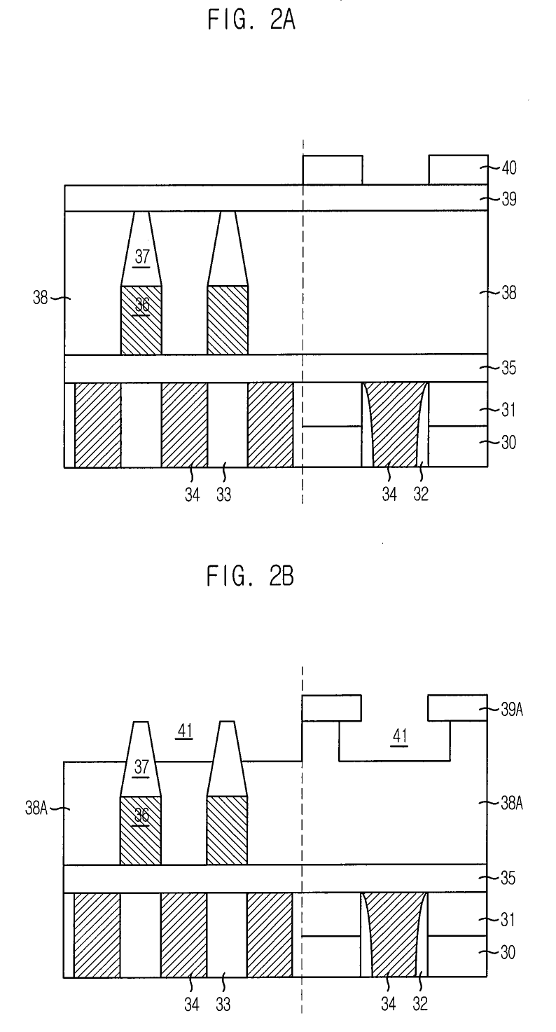

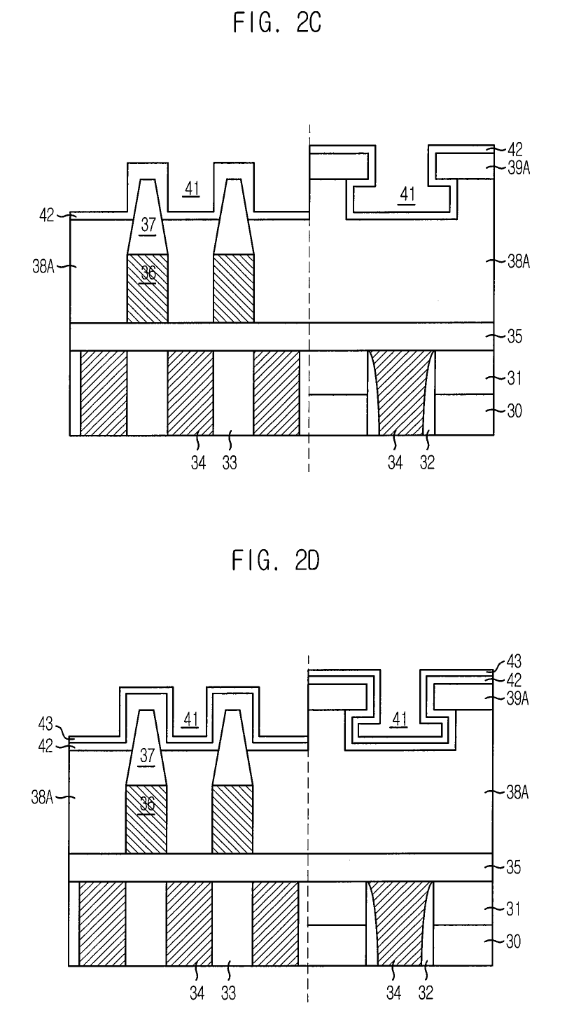

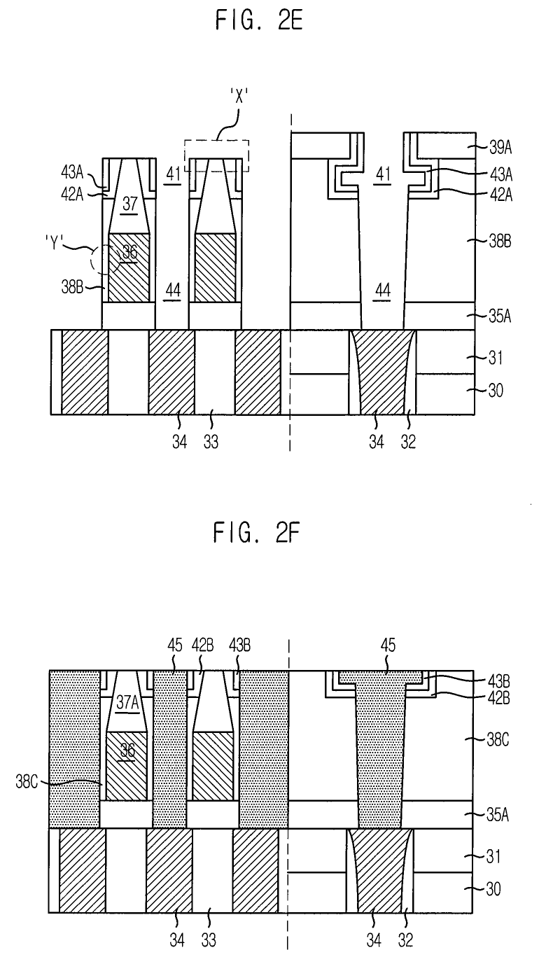

FIGS. 2A to 2F illustrate cross-sectional views to describe a method for fabricating a storage node contact in accordance with an embodiment of the present invention. Each of the cross-sectional views is divided into two sections by a perforated line. A section on the left side of the perforated line shows the cross-sectional view cut across bit line patterns, and a section on the right side of the perforated line shows the cross-sectional view cut parallel to the bit line patterns. Hereinafter, both directions of the cross-sectional views are described in detail.

Referring to FIG. 2A, gate patterns including a gate conductive layer 30, a gate hard mask 31, and gate spacers 32 are formed. An insulation layer is formed over the gate patterns, and then, a chemical mechanical polishing (CMP) process is performed to planarize the insulation layer to form a first inter-layer insulation layer 33. The first inter-layer insulation layer 33 includes an oxide-based material. The oxide-based material may include a borophosphosilicate glass (BPSG) or high density plasma (HDP) oxide layer.

Portions of the first inter-layer insulation layer 33 formed between the gate patterns are selectively etched, and landing plug contacts 34 are formed in the etched portions of the first inter-layer insulation layer 33. The landing plug contacts 34 may include polysilicon.

A second inter-layer insulation layer 35 is formed over the resultant substrate structure. The second inter-layer insulation layer 35 includes an oxide-based material. The oxide-based material may include a BPSG or HDP oxide layer.

Bit line patterns are formed over predetermined portions of the second inter-layer insulation layer 35. The bit line patterns are formed perpendicular to the gate patterns. Each of the bit line patterns includes a bit line conductive layer 36 and a bit line hard mask 37 formed in sequential order. The bit line conductive layer 36 includes one selected from a group consisting of tungsten (W), titanium (Ti), tungsten nitride (WN), tungsten silicide (WSi), and a combination thereof. The bit line hard mask 37 includes a nitride-based material such as silicon oxynitride (SiON) or silicon nitride (SiN).

An HDP oxide layer is formed over the substrate structure and filled between the bit line patterns. Then, a CMP process is performed to planarize the HDP oxide layer until top surfaces of the bit line patterns to form a third inter-layer insulation layer 38.

A hard mask layer 39 is formed over the planarized third inter-layer insulation layer 38, and line type contact masks 40 are formed over the hard mask layer 39. The hard mask layer 39 may include polysilicon. The contact masks 40 function as storage node contact masks formed in line type and perpendicular to the bit line patterns.

Referring to FIG. 2B, the hard mask layer 39 is etched using the contact masks 40 as an etch barrier to form line type hard mask patterns 39A. Then, the contact masks 40 are removed.

A partial etching process is performed onto the third inter-layer insulation layer 38 to form openings, using the hard mask patterns 39A as an etch barrier. Then, a wet etching process is performed to enlarge a width of the openings, thereby forming first open regions 41 and a patterned third inter-layer insulation layer 38A.

The partial etching process includes performing a dry etching process, and is performed under a predetermined etch condition having a selectivity to nitride-based materials. The etch condition is referred to as a self-aligned contact (SAC) recipe. For instance, the etch condition may include using a pressure ranging from approximately 15 mT to approximately 50 mT and a power ranging from approximately 1,000 W to approximately 2,000 W. The etch condition uses a gas including argon (Ar), oxygen (O₂), carbon monoxide (CO), and nitrogen (N₂) in addition to at least one gas selected from a group consisting of carbon tetrafluoride (CF₄), C₄F₈, C₅F₈, C₄F₆, trifluoromethane (CHF₃), and difluoromethane (CH₂F₂). Accordingly, performing the partial etching process using the above etch condition having the selectivity to nitride-based materials allows reducing damages of the bit line hard masks 37 which may be exposed during the partial etching process.

Also, the wet etching process for enlarging the width of the openings may be performed using a hydrogen fluoride (HF)-based solution at a ratio of water to HF ranging approximately 20-300:1. The HF-based solution may include buffered oxide etchant (BOE) or HF. Since the third inter-layer insulation layer 38 includes an HDP oxide layer, the third inter-layer insulation layer 38 can be selectively etched without damaging the hard mask patterns 39A and the bit line hard masks 37.

Referring to FIG. 2C, a capping layer 42 is formed over the substrate structure and in the first open regions 41. Portions of the capping layer 42 are formed on top portions of the bit line patterns to a sufficient thickness. The capping layer 42 includes an oxide-based layer, i.e., undoped silicate glass (USG) layer, having a thickness ranging from approximately 500 Å to approximately 1,000 Å in order to reduce a thickness loss of sidewalls of the bit line patterns during subsequent etching processes.

The USG layer includes an oxide-based material having a low step coverage characteristic. Thus, the portions of the USG layer formed on the top portions of the bit line patterns have a larger thickness than portions of the USG layer formed between the bit line patterns and on the sidewalls of the bit line patterns, adjusting a profile of the bit line patterns. When performing a patterning process to form the bit line patterns, a profile of the bit line hard masks 37 obtains a trapezoid form, each bit line hard mask 37 having a narrower upper portion and a wider bottom portion. However, when the capping layer 42 is formed, the profile of the bit line patterns transforms into a rectangular type profile due to a capping effect of the capping layer 42. The capping layer 42 is formed to adjust the profile of the bit line patterns.

Meanwhile, the capping layer 42 may include a nitride-based layer having a low step coverage characteristic. For instance, the step coverage characteristic can be controlled by forming the nitride-based layer using a plasma enhanced chemical vapor deposition (PECVD) method.

Referring to FIG. 2D, a spacer layer 43 is formed over the capping layer 42 to enlarge the thickness of the sidewalls of the bit line patterns. The spacer layer 43 has a thickness ranging from approximately 50 Å to approximately 500 Å. The spacer layer 43 includes a nitride-based layer such as SiON or SiN.

Referring to FIG. 2E, a storage node contact spacer etching process is performed to form second open regions 44. During the storage node contact spacer etching process, the capping layer 42 formed over the bit line patterns largely reduces a loss of the bit line hard masks 37.

The second open regions 44 are formed by sequentially etching predetermined portions of the spacer layer 43, the capping layer 42, the patterned third inter-layer insulation layer 38A, and the second inter-layer insulation layer 35, in-situ. Consequently, the second open regions 44 expose the landing plug contacts 34, and spacers 43A, patterned capping layers 42A, remaining third inter-layer insulation layers 38B, and patterned second inter-layer insulation layers 35A are formed. The patterned capping layers 42A and the spacers 43A remain on sidewalls of the bit line hard masks 37 as a form of contact spacer. Meanwhile, the etching of the oxide-based materials such as the capping layer 42, the second inter-layer insulation layer 35, and the patterned third inter-layer insulation layer 38A to form the second open regions 44 is performed under a predetermined etch condition having a selectivity to nitride-based materials. Such etch condition is referred to as a SAC recipe. For instance, the etch condition may include using a pressure ranging from approximately 15 mT to approximately 50 mT and a power ranging from approximately 1,000 W to approximately 2,000 W. The etch condition uses a gas including Ar, O₂, CO, and N₂ in addition to at least one gas selected from a group consisting of CF₄, C₄F₈, C₅F₈, C₄F₆, CHF₃, and CH₂F₂. Also, the spacer layer 43 is etched using CF₄ gas.

The first open regions 41 and the second open regions 44 configure storage node contact holes. The etching process for forming the first open regions 41 is referred to as a first storage node contact etching process, and the etching process for forming the second open regions 44 is referred to as a second storage node contact etching process.

The top portions of the bit line patterns obtain a rectangular type profile as represented with a reference letter ‘X’ after the second storage node contact etching process is performed. By transforming the spire type profile of the bit line hard masks 37 into the stable rectangular type profile X, a stable sidewall thickness Y can be obtained at both sidewalls of the bit line patterns. The sidewall thickness ‘Y’ increases by as much as the thickness of the patterned capping layers 42A.

The capping layer 42 reduces an etch loss of the bit line hard masks 37, and consequently, a prominence type profile that generally occurs after the first and second storage node contact etching processes does not occur. Thus, critical dimensions (CD) for isolation between adjacent storage node contacts increase largely during a subsequent CMP process. At the same time, a large remaining thickness of the bit line hard masks 37 can be maintained even after the CMP process.

Referring to FIG. 2F, polysilicon is filled into the storage node contact holes including the first open regions 41 and the second open regions 44. A storage node contact plug polysilicon (SPP) CMP process is performed to form storage node contacts 45 filled in the storage node contact holes. During the SPP CMP process, the hard mask patterns 39A are polished away, and remaining spacers 43B, remaining capping layers 42B, residual third inter-layer insulation layers 38C, and remaining bit line hard masks 37A are formed.

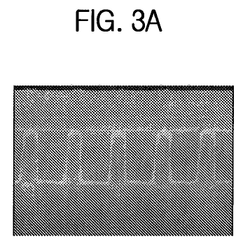

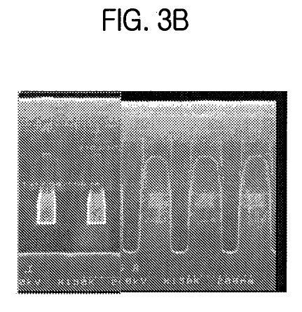

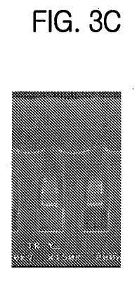

FIG. 3A illustrates a micrographic view of a profile of bit line patterns after a storage node contact etching process is performed and a capping layer is applied. FIG. 3B illustrates a micrographic view of a profile of bit line patterns after an etching process is performed to form storage node contact spacers. FIG. 3C illustrates a micrographic view of a profile of bit line patterns after a SPP CMP process is performed.

Referring to FIG. 3A, top portions of bit line patterns have a rectangular type profile. The rectangular type profile is obtained by forming a USG layer having a low step coverage characteristic over the bit line patterns. Thus, both sidewalls of the bit line patterns maintain a sufficient thickness.

Referring to FIG. 3B, effects of applying a capping layer include a reduced loss in bit line hard masks during a subsequent nitride-based spacer formation and a second storage node contact etching process, and maintaining of a sufficient sidewall thickness.

Referring to FIG. 3C, a prominence type profile of bit line patterns often generated after an etching process for forming the storage node contact hole can be reduced, resulting in an improved process margin during a subsequent CMP process.

The following table shows comparisons between a conventional semiconductor device and a semiconductor device consistent with an embodiment of the present invention with respect to thicknesses of remaining bit line hard masks, sidewall thicknesses, and CD for isolation between storage node contacts.

TABLE 1

| | | | | | Semiconductor | |
|---|---|---|---|---|---|---|
| | | | Conventional | | Device of the | |
| | | | Semiconductor | | Present | |
| | Target | | Device | | Embodiment | |
| Thickness of | >1,000 | Å | 914 | Å | 1,221 | Å |
| remaining bit | | | | | | |
| line hard masks | | | | | | |
| Sidewall | 250 | Å | 190 | Å | 264 | Å |
| thickness | | | | | | |
| CD for isolation | >60 | nm | 40 | nm | 80 | nm |

Referring to Table 1, the thickness of the remaining bit line hard masks, the sidewall thickness, and the CD for isolation in the semiconductor device in accordance with an embodiment of the present invention are larger than those of the conventional semiconductor device.

Also, unlike the conventional semiconductor device, the semiconductor device in accordance with embodiments of the present invention show larger values of the thickness of the remaining bit line hard masks, the sidewall thickness, and the CD for isolation when compared to the target values.

Consistent with embodiments of the present invention, a desired thickness of the insulation layers remaining on both sidewalls of the bit line patterns can be obtained. As the capping layer is applied, the sidewall loss, often occurring in conventional bit line patterns, caused by the asymmetrical sidewalls is improved. Furthermore, the thickness of the remaining bit line hard masks may be increased largely, wherein the remaining bit line hard masks are used for securing the isolation margin between the storage node contacts.

A sufficient level of critical dimensions for isolation can be obtained during the CMP process of the storage node contacts through forming the top portions of the bit line patterns in the stable rectangular type profile.

The present application contains subject matter related to the Korean patent application No. KR 2006-0001835, filed in the Korean Patent Office on Jan. 6, 2006, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a storage node contact in a semiconductor device, the method comprising:
forming a plurality of bit line patterns, each bit line pattern including a bit line hard mask formed over a bit line conductive layer;
forming an inter-layer insulation layer filled between the bit line patterns;
planarizing the inter-layer insulation layer until top portions of the bit line hard masks are exposed;
partially etching the inter-layer insulation layer to form first open regions;
enlarging a width of the first open regions;
forming a capping layer to cover the top portions of the bit line hard masks and to cover a surface of the first open regions;
etching the capping layer and remaining portions of the inter-layer insulation layer between the bit line patterns to form second open regions below the first open regions; and
forming storage node contacts filling in the first and second open regions.

2. The method of claim 1, wherein forming the capping layer comprises controlling a step coverage characteristic to generate a rectangular type profile at the top portions of the bit line patterns.

3. The method of claim 2, wherein forming the capping layer comprises controlling the step coverage characteristic in a manner that portions of the capping layer formed on the top portions and sidewalls of the bit line patterns have a larger thickness than portions of the capping layer formed on the inter-layer insulation layer between the bit line patterns.

4. The method of claim 1, wherein forming the capping layer comprises including an oxide-based layer.

5. The method of claim 4, wherein the capping layer comprises an undoped silicate glass (USG) layer.

6. The method of claim 5, wherein the capping layer has a thickness ranging from approximately 500 Å to approximately 1,000 Å.

7. The method of claim 1, wherein forming the capping layer comprises including a nitride-based layer.

8. The method of claim 1, further comprising, forming a spacer layer over the capping layer after forming the capping layer.

9. The method of claim 8, wherein forming the spacer layer comprises including a nitride-based layer.

10. The method of claim 9, wherein the spacer layer comprises silicon oxynitride (SiON) or silicon nitride (SiN).

11. The method of claim 9, wherein the spacer layer has a thickness ranging from approximately 50 Å to approximately 500 Å.

12. The method of claim 9, wherein forming the second open regions comprises etching the capping layer, the spacer layer, and the inter-layer insulation layer in-situ.

13. The method of claim 12, wherein etching the spacer layer using carbon tetrafluoride (CF₄) gas.

14. The method of claim 12, wherein etching the capping layer and the inter-layer insulation layer comprises using a self-aligned contact (SAC) recipe including an etch condition having a selectivity to a nitride-based layer.

15. The method of claim 14, wherein etching the capping layer and the inter-layer insulation layer comprises using a pressure ranging from approximately 15 mT to approximately 50 mT and a power ranging from approximately 1,000 W to approximately 2,000 W.

16. The method of claim 15, wherein etching the capping layer and the inter-layer insulation layer comprises using a gas including one or more selected from the group consisting of argon (Ar), oxygen (O₂), carbon monoxide (CO), and nitrogen (N₂).

17. The method of claim 16, wherein etching the capping layer and the inter-layer insulation layer comprises further using at least one selected from a group consisting of CF₄, C₄F₈, C₅F₈, C₄F₆, trifluoromethane (CHF₃), and difluoromethane (CH₂F₂).

18. The method of claim 1, wherein forming the bit line patterns comprises forming a nitride-based hard mask as the uppermost layer.

19. The method of claim 1, wherein forming the storage node contacts comprises using a storage node contact plug polysilicon (SPP) chemical mechanical polishing (CMP) process.
